(19) United States
(12) Patent Application Publication
(10) Pub. No.: US 2011/0197809 A1
(43) Pub. Date: Aug. 18, 2011

(54) SINGLE CRYSTAL COOLER AND SINGLE CRYSTAL GROWER INCLUDING THE SAME

(76) Inventors: Hyon-Jong Cho, Gumi-si (KR); Hong Woo Lee, Gumi-si (KR); Min-Seok Kwak, Gumi-si (KR); Ji-Hun Moon, Gumi-si (KR)

(21) Appl. No.: 13/027,063

(22) Filed: Feb. 14, 2011

(30) Foreign Application Priority Data
Feb. 12, 2010 (KR) 10-2010-0013326

(51) Int. Cl. C30B 11/02; F25D 23/06; B82Y 30/00

(52) U.S. Cl. 117/204; 62/451; 977/742

(57) ABSTRACT

Provided are a single crystal cooler and a single crystal grower including the same. The single crystal cooler includes a cooling main body and a passage. The passage is formed on an inner wall and an outer wall of the cooling main body. The passage allows cooling materials to move therethrough. The single crystal cooler has a cylindrical shape. A first inner diameter R1 of the single crystal cooler is about 1.5 times or more greater than an inner diameter R2 of a single crystal grown by applying the single crystal cooler.

### CROSS-REFERENCE TO RELATED APPLICATION

This application claims the priority benefit of Korean patent application number 10-2010-0013326, filed Feb. 12, 2010, the disclosure of which is incorporated by reference.

### BACKGROUND OF THE INVENTION

1. Field of the Invention

The present disclosure relates to a single crystal cooler and a single crystal grower including the same.

2. Description of the Related Art

A wafer must be formed to manufacture a semiconductor, and single crystal silicon must be grown in an ingot form to manufacture the wafer.

In general silicon used as materials of semiconductor circuit, single crystal is grown by a Czochralski (hereinafter, referred to as CZ) method. In recent years, quality requirements on such silicon single crystal become stricter.

In growth of silicon single crystal according to the CZ method, cooling velocity of crystal is a factor having a significant effect on growth rate of crystal and formation behaviors of various growth defects.

In a typical single crystal ingot grower, a water cooling pipe is an apparatus for rapidly cooling single crystal ingot pulled and grown from silicon melt in a melting pot.

A typical water cooling pipe is installed in an upper portion of a growth chamber to be positioned in a hot-zone, and cools the single crystal ingot pulled into a vacant space of the water cooling pipe during circulation of cooling water flowing therein.

However, since the typical water cooling pipe has a surface that is opaque and lustrous like a mirror, the typical water has a limitation in absorbing radiant heat emitted from the single crystal and hot-zone. This causes reduction of the pulling rate of the ingot, and thereby various limitations, for example, in that hot-zone structure in a growth furnace must be changed.

To solve the above limitations, various attempts have been made to improve the typical water cooling pipe, but there is a limitation in effective control of crystal defects in a single crystal.

### SUMMARY OF THE CLAIMED INVENTION

Embodiments provide a single crystal cooler and a single crystal grower including the same, which can substantially maximize the cooling efficiency of a silicon single crystal.

In one embodiment, a single crystal grower includes: a chamber for growth of a single crystal; a melting pot provided in the chamber; a heater heating the melting pot; and a cooler cooling the single crystal growing in the chamber, wherein the single crystal cooler has a cylindrical shape, and a first inner diameter R1 of the single crystal cooler is about 1.5 times or more greater than an inner diameter R2 of the single crystal.

In another embodiment, a single crystal grower includes: a chamber for growth of a single crystal; a melting pot provided in the chamber; a heater heating the melting pot; and a cooler cooling the single crystal growing in the chamber, wherein the single crystal cooler has a cylindrical shape, and a first inner diameter R1 of the single crystal cooler is about 1.5 times or more greater than an inner diameter R2 of the single crystal.

### BRIEF DESCRIPTION OF THE DRAWINGS

FIG. 1 illustrates a single crystal grower.

FIG. 2 illustrates an upper surface of a single crystal cooler.

FIG. 3 illustrates a cross-section of a single crystal cooler.

FIG. 4 illustrates an effect upon single crystal growth using a single crystal grower including a single crystal cooler.

### DETAILED DESCRIPTION

In the descriptions of embodiments, it will be understood that when a layer (or film), a region, a pattern, or a structure is referred to as being ‘on/above/over/upper’ substrate, each layer (or film), a region, a pad, or patterns, it can be directly on substrate each layer (or film), the region, the pad, or the patterns, or intervening layers may also be present. Further, it will be understood that when a layer is referred to as being ‘under/below/lower’ each layer (film), the region, the pattern, or the structure, it can be directly under another layer (film), another region, another pad, or another patterns, or one or more intervening layers may also be present. Therefore, meaning thereof should be judged according to the spirit of the present disclosure. Further, the reference about ‘on’ and ‘under’ each layer will be made on the basis of drawings.

In the drawings, the thickness or size of each layer is exaggerated, omitted, or schematically illustrated for convenience in description and clarity. Also, the size of each element does not entirely reflect an actual size.

FIG. 1 is a view illustrating a single crystal grower. A single crystal grower 100 according to an exemplary embodiment may include a chamber 110, a melting pot 120, a heater 130, a pulling means 140, and a cooler 160.

For example, a single crystal grower 100 according to an exemplary embodiment may include a chamber 110, a melting pot 120 provided in the chamber and receiving silicon solution, a heater 130 provided in the chamber 110 and heating the melting pot 120, and a cooler 160 cooling single crystal upon single crystal growth.

The chamber 110 may provide spaces in which certain processes are performed to grow single crystal ingot for silicon wafers that are used as materials of electric components such as semiconductors. Here, Examples of representative methods for growing silicon single crystal ingot may include a Czochralsk (CZ) method of growing crystal by dipping seed crystal S of single crystal in silicon melt SM and then slowly pulling the seed crystal S in the silicon melt SM.

The singly crystal growth according to the above method may include a necking process of growing thin and long crystal from the seed crystal S, a shouldering process of growing the crystal in a diameter direction to achieve a target diameter, a body growing process of growing the crystal to have a certain diameter, and then a tailing process of separate the crystal from melting silicon by slowly reducing the diameter of the crystal after the body growing process is performed to have a certain length.

A radiation insulator 132 may be installed at the inner wall of the chamber 110 to prevent heat of the heater 130 from being emitted to the sidewall portion of the chamber 110.

In an embodiment, various factors such as rotation speed of the quartz melting pot 120 and internal pressure condition of the chamber may be adjusted to control oxygen concentration in silicon single crystal growth. For example, argon gas may be injected into the chamber 110 of the silicon single crystal grower and may be discharged through a lower portion of the chamber 110, to control the oxygen concentration.

The melting pot 120 may be provided in the chamber 110 to contain silicon melt SM and may be formed of quartz material. A melting pot support 122 formed of graphite may be provided at the outside of the melting pot 120 to support the melting pot 120. The melting pot support 122 may be fixedly installed on a rotation axis 125. The rotation axis 125 may be rotated by a driving means (not shown) to allow the rotation movement and the rise and fall movement of the melting pot 120, thereby enabling solid-liquid interface to be maintained at the same height.

The heater 130 may be provided in the chamber 110 to heat the melting pot 120. For example, the heater 130 may be formed to have a cylindrical shape surrounding the melting pot support 122. The heater 130 may melt high purity polycrystalline silicon mass loaded in the melting pot 120 into silicon melts SM.

The pulling means 140 may be installed at an upper portion of the chamber 110 to pull up through a cable. A seed crystal S may be installed at a lower portion of the cable and contact the silicon melt SM in the melting pot 120 to grow a single crystal ingot IG during pulling. The pulling means 140 may perform a rotation movement while winding and pulling the cable during growth of the single crystal ingot IG. In this case, the single crystal ingot IG may be pulled up while being rotated in the opposite direction to the rotation direction of the melting pot 120 around the same axis as the rotation axis 125 of the melting pot 120.

A heat shield 150 may be installed between the single crystal ingot IG and the silicon melt SM to intercept heat from the melting pot 120 during the growth of the single crystal ingot IC.

Hereinafter, technical backgrounds on the single crystal cooler and the single crystal grower including the same according to an embodiment will be described.

With the advent of nano-technology semiconductor memory devices having a circuit linewidth of about several tens of nano scale, the crystal defect standard in a silicon wafer is more strictly regulated. For example, only the defect of about 100 nm has been standardized in 2000, but defects of about 45 nm and even about 37 nm become problems recently.

Embodiments may employ a V/C control technology based on Voronkov theory as a defect-free silicon single crystal manufacturing method. Here, V is a growth rate (i.e., pulling rate), and G is a temperature gradient around the growth interface. When a V/C parameter is maintained near a specific threshold value during the crystal growth, the concentration of point defect generated during crystallization may be allowed not to be supersaturated, thereby obtaining a defect-free signal crystal in which only the point defects exist without an agglomerated crystal defect.

However, since it is almost impossible to maintain the temperature gradient constantly in a direction of a crystal radius, a margin of a defect-free pulling rate may be narrowed. When a silicon single crystal is grown in practice, the pulling rate may be controlled to obtain a certain diameter of a single crystal. Accordingly, a slight deviation from the margin of the pulling rate and a super-saturation of the point detects may be generated.

If a vacancy super-saturation that is Vacancy-rich is slightly generated during the crystal growth, energy may be thermodynamically increased due to oversaturation. In this case, an agglomeration may occur to dissolve the oversaturation. The agglomeration may be treated as a sort of physical chemistry kinetics.

Recently, technologies are being studied to control generation of void defects, but there is a limitation in controlling defects of a level of about 20 nm size that is a recent issue.

Thus, embodiments provide a single crystal cooler and a single crystal grower using the same, which maximize the cooling efficiency of silicon single crystal substantially.

A process of forming crystal defects may include (i) a point defect formation stage in which liquid is crystallized into solid and (ii) an interaction stage in which crystals are agglomerated to each other due to super-saturation during cooling of the crystals. The behavior of the above crystal defect formation may be expressed as the following Equation (1):

Cv=f(V/Gs−ξ) (1)

where C is zero when V/Gs≦ξ, and increases along with the increase of V/Gs.

Cv is a vacancy concentration in a crystal just after crystallization, and is determined by a difference of V/Gs from a threshold ξ according to the Voronkov theory. Cv increases along with the increase of the crystal pulling rate V or the decrease of the vertical temperature gradient Gs in the crystal around the solid-liquid interface. The vacancy concentration Cv may be experimentally simplified into a primary equation like the following Equation (2) described below. Also, V/Gs may be expressed as the following Equation (3) from a heat-balance equation:

Cv∝1−ξ/(V/Gs) (2)

V/Gs=(Ks/L)−(K_{L}/L)·(G_{L}/Gs) (3)

where Ks is a heat transfer coefficient of a solid phase, KL is a heat transfer coefficient of a liquid phase, Gs is a vertical temperature gradient, and GL is a vertical temperature gradient.

Thus, a single crystal pulling rate V may be expressed as the following Equation 4:

V=(Ks/L)·Gs−(K_{L}·G_{L})/L (4)

From the above, it can be understood that the vertical temperature gradient Gs of crystal is an important factor that determines an initial vacancy concentration.

As described above, when the initial vacancy concentration is determined, behaviors such as agglomeration due to super-saturation and external diffusion may occur during cooling process of the crystal. Such a vacancy behavior may be affected by the cooling velocity. The cooling velocity Q may be expressed as the following Equation (5) because the cooling velocity Q is in direct proportion to the temperature gradient (temperature difference per unit length) of crystal and the pulling rate at which crystal is pulled per unit time.

Here, when V is substituted with Equation (4), Q is in proportion to the square of Gs as described in Equation 5. That is, since the cooling velocity Q is considerably affected by Gs, the improvement of Gs may be expected to more effectively control the agglomeration behavior of vacancy.

Q=V×(αGs)=α{(Ks/L)×Gs²−(K_{L}×G_{L}×Gs)/L} (5)

where α is a proportional constant of Gs around the solid-liquid interface and Gs of V-rich defect formation temperature section, and has a value of about 0.5 to about 1.5 according to the configurations of a heat-shield and a cooler.

According to the above description, it can be understood that the temperature gradient Gs of crystal has a great influence on the point defect concentration and crystal defect behavior.

Also, it is necessary to control the point defect agglomeration through rapid cooling upon interaction between point defects due to super-saturation of the point defect concentration during the cooling process after crystallization. To this end, it is desirable to further improve the temperature gradient Gs of crystal.

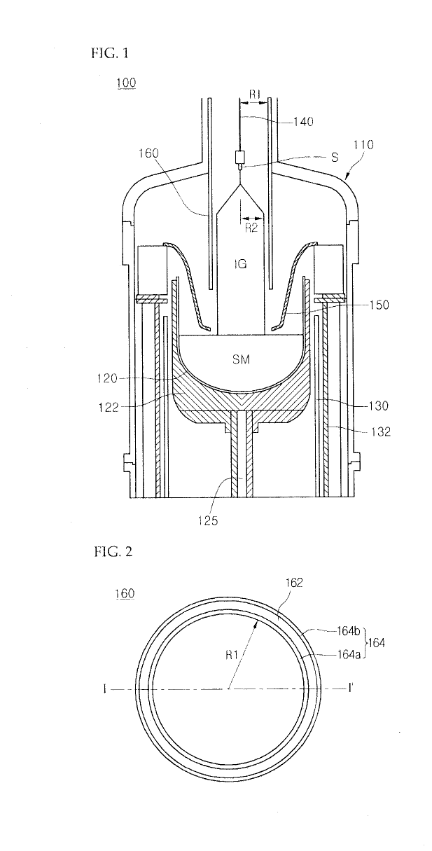

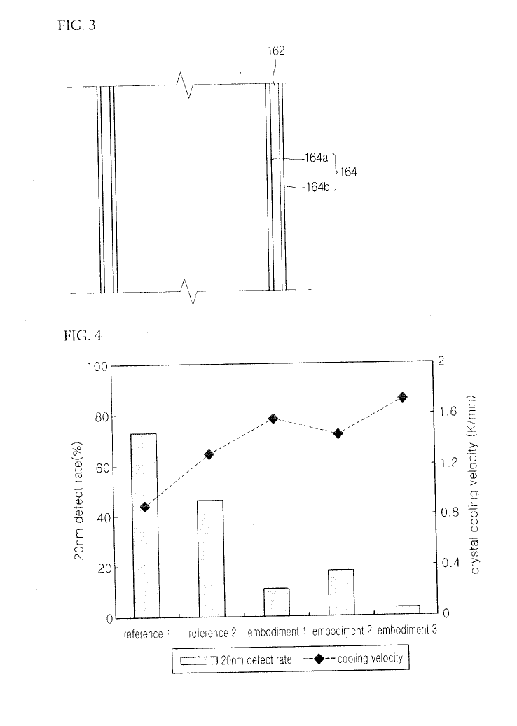

FIG. 2 is a view illustrating an upper surface of a single crystal cooler 160 according to an exemplary embodiment, and FIG. 3 is a view illustrating a cross-section of the single crystal cooler 160 according to the exemplary embodiment.

Embodiments relate to substantial control of crystal defects of about 20 nm by overcoming a limitation of a cooling efficiency increase in a related-art. In order to an increase of the cooling efficiency, it is necessary to absorb more radiant heat from a single crystal in growth. Two methods are proposed as the following Equation (6):

Radiation_Heat=Aεσ×(T_{crystal}⁴−T_{cooler}⁴) (6)

where A is a surface of a cooler, ε is a radiation rate, σ is a Boltzmann constant, Tcrystal is a surface temperature of a crystal, and Tcooler is a surface temperature of the cooler.

In an embodiment, a surface area must be broadened by increasing the inner diameter R1 of the cooler, and a radiation rate of the surface of, the cooler must be further increased to control the crystal defect of about 20 nm.

A single crystal cooler 160 according to an embodiment may have a cylindrical shape. A first inner diameter R1 of the single crystal cooler may be about 1.5 times or more greater than an inner diameter R2 of a single crystal that is grown by applying the single crystal cooler. For example, the first inner diameter R1 of the single crystal cooler may be about 1.5 times to about 2.0 times greater than the inner diameter R2 of the single crystal that is grown by applying the single crystal cooler, but embodiments are not limited thereto.

Also, the single crystal cooler 160 according to an embodiment may include a cooling main body 162, a passage (not shown) on the inner wall and the outer wall of the cooling main body 162, and a coating layer 164 formed on the surface of the cooling main body 162. Cooling materials may move through the passage (not shown). The cooling materials may be cooling water, but embodiments are not limited thereto.

For example, the coating layer 164 may include a first coating layer 164a formed on the inner surface of the cooling main body 162 and a second coating layer 164b formed on the outer surface of the cooling main body 162, but embodiments are not limited thereto.

In an embodiment, the coating layer 164 may be a carbon nanotube or a ceramic coating layer that may maximize the radiation rate of the surface of the cooler, but embodiments are not limited thereto.

FIG. 4 is a view illustrating an effect upon single crystal growth using a single crystal grower including a single crystal cooler according to an exemplary embodiment. The following Table 1 shows the cooling velocity and the defect rate experimental examples according to the inner diameter of a single crystal cooler and the material of a coating layer.

| | | Crystal | Crystal | |
|---|---|---|---|---|
| | | Temperature | cooling | |
| | | Gradient | velocity | 20 nm Defect |
| | Experimental Condition | (K/min) | (K/min) | Rate (5) |
| Comparative | Insert graphite tube into cooler | 1.79 | 0.877 | 73 |
| Example 1 | | | | |
| Comparative | Coat cooler with ceramic | 2.48 | 1.29 | 46 |
| Example 2 | | | | |
| Embodiment 1 | Coat cooler with ceramic | 2.73 | 1.56 | 11 |
| | Inner Dia(R1) of cooler = 1.5R2 | | | |
| Embodiment 2 | Coat cooler with carbon nanotube | 2.62 | 1.44 | 18 |
| Embodiment 3 | Coat cooler with carbon nanotube | 2.86 | 1.72 | 3 |
| | Inner Dia(R1) of cooler = 1.5R2 | | | |

A first comparative example shows an evaluated Gs value by tightly inserting a graphite tube having a cylindrical shape into a cooler, for example, a water cooling tube. A second comparative example shows an evaluated Gs value by coating the inner side of the water cooling tube with ceramic.

The Gs value was increased in the second comparative example compared to the first comparative example. However, the crystal cooling velocity was about 1.29 K/min, which did not reach a cooling velocity of a level (more than about 1.4 K/min) that may control crystal defects of about 20 nm. The pulling rate of the crystal was about 0.5 mm/min in the comparative examples.

In a first embodiment, it was verified that the crystal cooling velocity exceeded about 1.5 K/min by increasing the inner diameter R1 of a ceramic coating cooler by about 33% compared to a related art, and controlling the crystal pulling rate to enable a defect-free growth. The rate of 20 nm defect generation was considerably improved by allowing the cooling velocity to exceed about 1.5 K/min.

In a second embodiment, a Gs value was evaluated when the pulling rate of the crystal was increased to about 0.55 mm/min after a carbon nanotube was coated on the inner side of the cooler. The cooling velocity has reached about 1.44 K/min that is a level capable of controlling crystal defects of about 20 nm.

In a third embodiment, a Gs value was evaluated when the pulling rate of the crystal was increased to about 0.6 mm/min after the inner diameter R1 of the cooler was extended by about 33% compared to a related-art and a carbon nanotube was coated on the inner side of the cooler. In the third embodiment, a better 20 nm crystal defect control effect may be expected by increasing the cooling velocity compared to the first and second embodiments.

A single crystal cooler and a single crystal grower including the same according to embodiments can substantially maximize cooling efficiency by accurately analyzing a cooling process of silicon single crystal.

Also, according to embodiments, cooling efficiency can be improved to an optimum level by improving the shape or component design of the cooler. In addition, according to embodiments, productivity can be significantly improved by increasing pulling rate of crystal as well as improving the yield of products, 20 nm crystal defects of which are controlled.

A single crystal cooler and a single crystal grower including the same according to embodiments can substantially maximize cooling efficiency by accurately analyzing a cooling process of silicon single crystal. Also, according to embodiments, cooling efficiency can be improved to an optimum level by improving the shape or component design of the cooler.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effectuate such a feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A single crystal cooler, comprising:
a cooling main body; and
a passage on an inner wall and an outer wall of the cooling main body, the passage allowing for the movement of cooling materials, wherein the single crystal cooler has a cylindrical shape, and a first inner diameter R1 of the single crystal cooler is about 1.5 times or more greater than an inner diameter R2 of a single crystal grown by applying the single crystal cooler.

2. The single crystal cooler of claim 1, wherein the first inner diameter R1 of the single crystal cooler is about 1.5 times to about 2.0 times greater than the inner diameter R2 of the single crystal grown by applying the single crystal cooler.

3. The single crystal cooler of claim 1, further comprising a carbon nanotube coating layer on a surface of the cooling main body.

4. The single crystal cooler of claim 1, further comprising a ceramic coating layer on a surface of the cooling main body.

5. A single crystal grower comprising:
a chamber for growth of a single crystal;
a melting pot provided in the chamber;
a heater heating the melting pot; and
a cooler that cools the single crystal growing in the chamber, wherein the single crystal cooler has a cylindrical shape, and a first inner diameter R1 of the single crystal cooler is about 1.5 times or more greater than an inner diameter R2 of the single crystal.

6. The single crystal grower of claim 5, wherein the first inner diameter R1 of the single crystal cooler is about 1.5 times to about 2.0 times greater than the inner diameter R2 of the single crystal.

7. The single crystal grower of claim 5, wherein the cooler further comprises:
a cooling main body; and
a carbon nanotube coating layer on an inner surface of the cooling main body.

8. The single crystal grower of claim 7, further comprising a second coating layer on an outer surface of the cooling main body.

9. The single crystal grower of claim 5, wherein the cooler further comprises:
a cooling main body; and
a ceramic coating layer on an inner surface of the cooling main body.

10. The single crystal grower of claim 9, further comprising a second coating layer on an outer surface of the cooling main body.
